(19) United States
(12) Patent Application Publication
(10) Pub. No.: US 2023/0125774 A1
(43) Pub. Date: Apr. 27, 2023

(54) DYNAMIC RANDOM ACCESS MEMORY AND OPERATION METHOD THEREOF

(71) Applicant: NANYA TECHNOLOGY CORPORATION, New Taipei City (TW)

(72) Inventor: Nung Yen, Taoyuan City (TW)

(73) Assignee: NANYA TECHNOLOGY CORPORATION, New Taipei City (TW)

(21) Appl. No.: 17/510,405

(22) Filed: Oct. 26, 2021

(51) Int. Cl. G11C 11/406

(52) U.S. Cl. CPC G11C 11/40611

(57) ABSTRACT

A dynamic random access memory (DRAM) and an operation method thereof are provided. The DRAM includes a memory cell array, a refresh counter, a row hammer logic circuit, and a refresh logic circuit. The memory cell array includes a plurality of memory cell rows. The refresh counter provides a current refresh word line address. The row hammer logic circuit provides a victim word line address. The refresh logic circuit refreshes a target row during a first sub-period of a tRFC by using the current refresh word line address to perform an automatic refresh operation. The refresh logic circuit refreshes a victim row during a second sub-period of the same tRFC for row hammer protection by using the victim word line address.

### BACKGROUND

### Technical Field

The disclosure relates to a memory. Particularly, the disclosure relates to a dynamic random access memory (DRAM) and an operation method thereof.

### Description of Related Art

Row hammer is a physical leakage issue of a dynamic random access memory (DRAM). When a specific word line in the DRAM is repeatedly turned on multiple times, data stored in memory cells of a word line adjacent to the specific word line may be lost because of cross-talk or coupling effects. Such interference is referred to as row hammer. An auto-refresh command, to a certain extent, may prevent the data loss due to row hammer. At the automatic refresh command, each word line of the DRAM chip is scanned, that is, the memory cells of one word line after another are refreshed. In any case, it takes an amount of time to completely refresh all of the rows (all of the word lines). In other words, for any one of the rows, a refresh time interval from the current refresh to the next refresh is rather long and lacks flexibility. When a certain word line (also referred to as aggressor word line) is frequently turned on multiple times during one refresh time interval, data may be lost because of the frequent row hammer before an automatic refresh operation is executed on the memory cells of the adjacent word line (also referred to as victim word line). How to prevent the data loss due to row hammer is one of many technical issues in the technical field.

### SUMMARY

The disclosure provides a dynamic random access memory (DRAM) and an operation method thereof to provide row hammer protection.

In an embodiment of the disclosure, the DRAM includes a memory cell array, a refresh counter, a row hammer logic circuit, and a refresh logic circuit. The memory cell array includes a plurality of memory cell rows. A refresh counter is configured to provide a current refresh word line address for an automatic refresh operation. The current refresh word line address corresponds to a target row in the memory cell rows. The row hammer logic circuit is configured to provide a victim word line address for a row hammer protection. The victim word line address corresponds to a victim row in the memory cell rows. The refresh logic circuit is coupled to the refresh counter and the row hammer logic circuit to receive the current refresh word line address and the victim word line address. The refresh logic circuit is configured to enter a row refresh cycle time based on a refresh command issued by a memory controller. The refresh logic circuit refreshes the target row during a first sub-period of the row refresh cycle time by using the current refresh word line address to perform the automatic refresh operation. The refresh logic circuit refreshes the victim row during a second sub-period of the row refresh cycle time by using the victim word line address to perform the row hammer protection.

In an embodiment of the disclosure, the operation method includes the following. A current refresh word line address for an automatic refresh operation is provided by a refresh counter of the DRAM. The current refresh word line address corresponds to a target row in a plurality of memory cell rows of a memory cell array of the DRAM. A victim word line address for a row hammer protection is provided by a row hammer logic circuit of the DRAM. The victim word line address corresponds to a victim row in the memory cell rows. A row refresh cycle time is entered based on a refresh command issued by a memory controller. The target row is refreshed by a refresh logic circuit of the DRAM during a first sub-period of the row refresh cycle time by using the current refresh word line address to perform the automatic refresh operation. The victim row is refreshed by the refresh logic circuit during a second sub-period of the row refresh cycle time by using the victim word line address to perform the row hammer protection.

Based on the above, in the embodiments of the disclosure, the DRAM enters the row refresh cycle time based on the refresh command issued by the memory controller. The refresh logic circuit may divide one row refresh cycle time into at least the first sub-period and the second sub-period. The refresh logic circuit may not only refresh the corresponding target row during the first sub-period of the row refresh cycle time by using the current refresh word line address provided by the refresh counter, but the refresh logic circuit may also refresh the corresponding victim row during the second sub-period of the same row refresh cycle time by using the victim word line address provided by the row hammer logic circuit. Therefore, the DRAM may selectively (flexibly) perform row hammer protection during any row refresh cycle time.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic circuit block diagram of a dynamic random access memory (DRAM) according to an embodiment of the disclosure.

FIG. 2 is a schematic timing diagram illustrating the automatic refresh operation.

FIG. 3 is a schematic flowchart of an operation method of a dynamic random access memory according to an embodiment of the disclosure.

FIG. 4 is a schematic timing diagram illustrating the automatic refresh operation according to an embodiment of the disclosure.

### DESCRIPTION OF THE EMBODIMENTS

The term “coupling (or connection)” used throughout the whole specification of the disclosure (including the appended claims) may refer to any direct or indirect connection means. For example, if it is herein described that a first device is coupled (or connected) to a second device, it should be interpreted that the first device may be directly connected to the second device, or the first device may be indirectly connected through other devices or some connection means to the second device. The terms “first”, “second”, and similar terms mentioned throughout the whole specification of the disclosure (including the appended claims) are merely used to name discrete elements or to differentiate among different embodiments or ranges, instead of limiting an upper bound or lower bound of the number of elements or the sequence of elements. In addition, wherever possible, elements/components/steps using the same reference numerals in the drawings and the embodiments denote the same or similar parts. Cross-reference may be mutually made between relevant descriptions of elements/components/steps using the same reference numerals or the same terms in different embodiments.

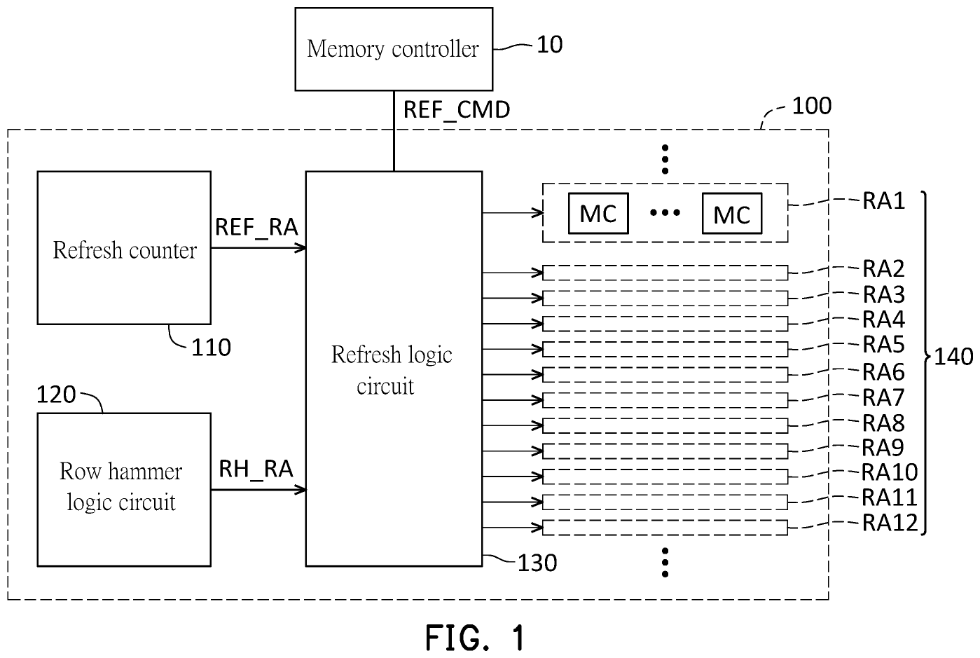

FIG. 1 is a schematic circuit block diagram of a dynamic random access memory (DRAM) 100 according to an embodiment of the disclosure. A memory controller 10 may control and access the DRAM 100. The DRAM 100 shown in FIG. 1 includes a refresh counter 110, a row hammer logic circuit 120, a refresh logic circuit 130, and a memory cell array 140. The memory cell array 140 includes a plurality of memory cell rows, for example, memory cell rows RA1, RA2, RA3, RA4, RA5, RA6, RA7, RA8, RA9, RA10, RA11, and RA12 as shown in FIG. 1. Each of the memory cell rows RA1 to RA12 includes a plurality of memory cell circuits MC. The specific implementation of the memory cell circuit MC is not limited by this embodiment. For example, depending on the actual design, the memory cell circuit MC may include a conventional memory cell circuit or other memory cell circuits. For clarity of the drawings, the word line, the bit line, and other circuits/elements of the memory cell array 140 are not shown in FIG. 1.

The refresh counter 110 may provide a current refresh word line address REF_RA for an automatic refresh operation. The current refresh word line address REF_RA corresponds to a target row in the memory cell rows (e.g., RA1 to RA12) of the memory cell array 140. According to the timing of scanning and refreshing the memory cell rows of the memory cell array 140, the refresh counter 110 may update the current refresh word line address REF_RA to point to the next memory cell row. The refresh logic circuit 130 is coupled to the refresh counter 110 to receive the current refresh word line address REF_RA.

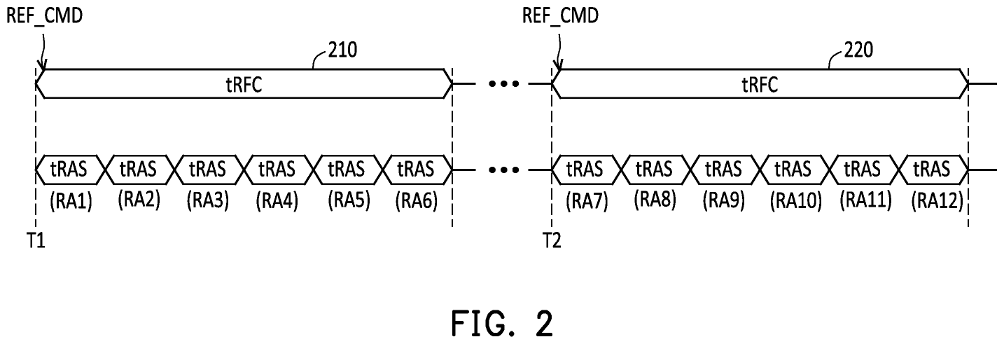

FIG. 2 is a schematic timing diagram illustrating the automatic refresh operation. The horizontal axis shown in FIG. 2 represents time. With reference to FIG. 1 and FIG. 2, based on a refresh command REF_CMD issued by the memory controller 10, the DRAM 100 may enter a row refresh cycle time. The row refresh cycle time may be “tRFC” specified in the DRAM standard. Each tRFC may include a plurality of RAS active times (i.e., row address strobe active time). The RAS active time may be “tRAS” specified in the DRAM standard. The definitions of “tRFC” and “tRAS” are known to those skilled in the art, and thus will not be repeatedly described herein. The number of tRAS in each tRFC may vary depending on the actual design. For example, in some embodiments, one tRFC may have a time length of 350 ns (nanosecond), one tRAS may have a time length of 50 ns to 60 ns, and the number of tRAS in one tRFC may be 6.

Based on the refresh command REF_CMD issued by the memory controller 10, the DRAM 100 may enter a row refresh cycle time (tRFC) 210 at a time point T1. During the row refresh cycle time 210, the refresh counter 110 may update the current refresh word line address REF_RA during different RAS active times (tRAS), and the refresh logic circuit 130 may refresh the target row (e.g., the memory cell rows RA1 to RA6) corresponding to the current refresh word line address REF_RA during each RAS active time. After the row refresh cycle time 210 ends, the refresh logic circuit 130 may suspend the automatic refresh operation. Based on another refresh command REF_CMD issued by the memory controller 10, the DRAM 100 may enter a row refresh cycle time (tRFC) 220 at a time point T2. During the row refresh cycle time 220, the refresh counter 110 and the refresh logic circuit 130 may resume the automatic refresh operation. The refresh counter 110 may update the current refresh word line address REF_RA during different RAS active times (tRAS) of the row refresh cycle time 220, and the refresh logic circuit 130 may refresh the target row (e.g., the memory cell rows RA7 to RA12) corresponding to the current refresh word line address REF_RA during each RAS active time (tRAS) of the row refresh cycle time 220.

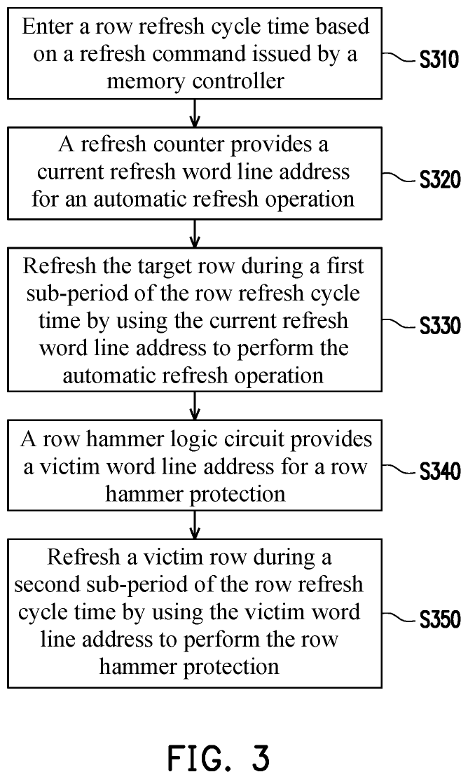

FIG. 3 is a schematic flowchart of an operation method of a dynamic random access memory (DRAM) according to an embodiment of the disclosure. With reference to FIG. 1 and FIG. 3, in step S310, based on the refresh command REF_CMD issued by the memory controller 10, the DRAM 100 may enter a row refresh cycle time (tRFC). The refresh logic circuit 130 may divide one row refresh cycle time into at least a first sub-period and a second sub-period. Based on the actual design, the first sub-period may include one or more RAS active times (tRAS), and the second sub-period may include one or more RAS active times (tRAS).

In step S320, the refresh counter 110 may provide the current refresh word line address REF_RA for an automatic refresh operation. The current refresh word line address REF_RA corresponds to a target row in the memory cell rows (e.g., RA1 to RA12) of the memory cell array 140. In step S330, the refresh logic circuit 130 may refresh the target row during the first sub-period of the row refresh cycle time (tRFC) by using the current refresh word line address REF_RA to perform the automatic refresh operation.

In step S340, the row hammer logic circuit 120 may provide a victim word line address RH_RA for row hammer protection. The victim word line address RH_RA corresponds to a victim row in the memory cell rows (e.g., RA1 to RA12) of the memory cell array 140. The specific implementation of the row hammer logic circuit 120 is not limited by this embodiment. Depending on the actual design, in some embodiments, the row hammer logic circuit 120 may count the number of turn-on times of each memory cell row of the memory cell array 140 during a period of time. A memory cell row having a number of turn-on times more than a threshold may be regarded as an aggressor word line, and a word line adjacent to this aggressor word line may be regarded as a victim word line. The row hammer logic circuit 120 may take the word line address (row address) of the victim word line as the victim word line address RH_RA. In some other embodiments, the row hammer logic circuit 120 may determine the victim word line address RH_RA by employing conventional row hammer algorithms or other row hammer algorithms.

The refresh logic circuit 130 is coupled to the row hammer logic circuit 120 to receive the victim word line address RH_RA. The refresh logic circuit 130 may enter the row refresh cycle time (tRFC) based on the refresh command REF_CMD issued by the memory controller 10. During the second sub-period of the row refresh cycle time (tRFC), the refresh logic circuit 130 may refresh the victim row by using the victim word line address RH_RA to perform the row hammer protection (step S350).

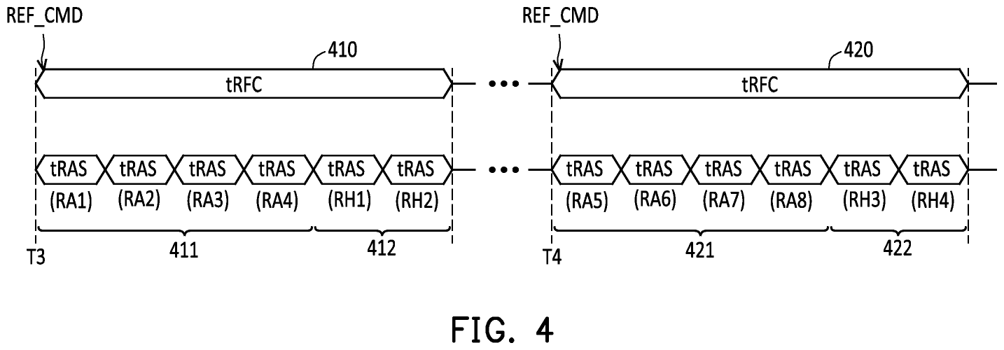

FIG. 4 is a schematic timing diagram illustrating the automatic refresh operation according to an embodiment of the disclosure. The horizontal axis shown in FIG. 4 represents time. With reference to FIG. 1, FIG. 3, and FIG. 4, based on the refresh command REF_CMD issued by the memory controller 10 at a time point T3, the refresh logic circuit 130 may enter a row refresh cycle time (tRFC) 410. The row refresh cycle time 410 may include a first sub-period 411 and a second sub-period 412. Depending on the actual design, the first sub-period 411 may include one or more RAS active times (tRAS), and the second sub-period 412 may include one or more RAS active times (tRAS). Similarly, based on another refresh command REF_CMD issued by the memory controller 10 at a time point T4, the refresh logic circuit 130 may enter a row refresh cycle time (tRFC) 420 having a first sub-period 421 and a second sub-period 422.

The refresh counter 110 updates the current refresh word line address REF_RA respectively during different RAS active times (tRAS) of the first sub-period 411 of the row refresh cycle time (tRFC) 410 (step S320). The refresh logic circuit 130 may refresh the target row (e.g., the memory cell rows RA1 to RA4) corresponding to the current refresh word line address REF_RA during each of the RAS active times (tRAS) of the first sub-period 411 by using the updated current refresh word line address REF_RA to perform the automatic refresh operation (step S330).

The row hammer logic circuit 120 updates the victim word line address RH_RA respectively during different RAS active times (tRAS) of the second sub-period 412 of the row refresh cycle time (tRFC) 410 (step S340). The refresh logic circuit 130 may refresh the victim row (e.g., memory cell rows RH1 and RH2 in the memory cell array 140) corresponding to the victim word line address RH_RA during each of the RAS active times (tRAS) of the second sub-period 412 by using the updated victim word line address RH_RA to perform the row hammer protection (step S350). Depending on the actual operating situation, any one of the memory cell rows RH1 and RH2 may be one of the memory cell rows RA1 to RA12, and may also be other memory cell rows in the memory cell array 140 not shown in FIG. 1. After the row refresh cycle time 410 ends, the refresh logic circuit 130 may suspend the automatic refresh operation.

During the row refresh cycle time (tRFC) 420, the refresh logic circuit 130 may resume the automatic refresh operation. The refresh counter 110 updates the current refresh word line address REF_RA respectively during different RAS active times (tRAS) of the first sub-period 421 of the row refresh cycle time 420 (step S320). The refresh logic circuit 130 may refresh the target row (e.g., the memory cell rows RA5 to RA8) corresponding to the current refresh word line address REF_RA during each of the RAS active times (tRAS) of the first sub-period 421 by using the updated current refresh word line address REF_RA to perform the automatic refresh operation (step S330).

The row hammer logic circuit 120 updates the victim word line address RH_RA respectively during different RAS active times (tRAS) of the second sub-period 422 of the row refresh cycle time (tRFC) 420 (step S340). The refresh logic circuit 130 may refresh the victim row (e.g., some other memory cell rows RH3 and RH4 in the memory cell array 140) corresponding to the victim word line address RH_RA during each of the RAS active times (tRAS) of the second sub-period 422 by using the victim word line address RH_RA to perform the row hammer protection (step S350). Depending on the actual operating situation, any one of the memory cell rows RH3 and RH4 may be one of the memory cell rows RA1 to RA12, and may also be other memory cell rows in the memory cell array 140 not shown in FIG. 1.

In summary of the foregoing, the DRAM 100 in this embodiment may enter the row refresh cycle time (tRFC) based on the refresh command REF_CMD issued by the memory controller 10. The refresh logic circuit 130 may divide one row refresh cycle time into at least the first sub-period and the second sub-period. For example, the row refresh cycle time 410 includes the first sub-period 411 and the second sub-period 412. The refresh logic circuit 130 may not only refresh the corresponding target row (e.g., the memory cell rows RA1 to RA4) during the first sub-period 411 of the row refresh cycle time (tRFC) 410 by using the current refresh word line address REF_RA provided by the refresh counter 110, but the refresh logic circuit 130 may also refresh the corresponding victim row (e.g., the memory cell rows RH1 and RH2) during the second sub-period 412 of the same row refresh cycle time 410 by using the victim word line address RH_RA provided by the row hammer logic circuit 120. Therefore, the DRAM 100 may selectively (flexibly) perform row hammer protection during any row refresh cycle time (tRFC).

Depending on different design requirements, the refresh counter 110, the row hammer logic circuit 120, and/or the refresh logic circuit 130 may be implemented in a form of hardware, firmware, software (programs), or a combination of more than one of the above three. For example, the refresh counter 110, the row hammer logic circuit 120, and/or the refresh logic circuit 130 may be implemented in a logic circuit on an integrated circuit. The relevant functions of the refresh counter 110, the row hammer logic circuit 120, and/or the refresh logic circuit 130 may be implement in the form of hardware by using hardware description languages (e.g., Verilog HDL or VHDL) or other suitable programming languages. The relevant functions of the refresh counter 110, the row hammer logic circuit 120, and/or the refresh logic circuit 130 may be implemented in one or more controllers, microcontrollers, microprocessors, application-specific integrated circuits (ASIC), digital signal processors (DSP), field programmable gate arrays (FPGA), and/or various logic blocks, modules, and circuits in other processing units.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A dynamic random access memory, comprising:
a memory cell array, comprising a plurality of memory cell rows;
a refresh counter, configured to provide a current refresh word line address for an automatic refresh operation, wherein the current refresh word line address corresponds to a target row in the memory cell rows;
a row hammer logic circuit, configured to provide a victim word line address for a row hammer protection, wherein the victim word line address corresponds to a victim row in the memory cell rows; and
a refresh logic circuit, coupled to the refresh counter and the row hammer logic circuit to receive the current refresh word line address and the victim word line address, and configured to enter a row refresh cycle time based on a refresh command issued by a memory controller,
wherein the refresh logic circuit refreshes the target row during a first sub-period of the row refresh cycle time by using the current refresh word line address to perform the automatic refresh operation, and
the refresh logic circuit refreshes the victim row during a second sub-period of the row refresh cycle time by using the victim word line address to perform the row hammer protection, wherein the row refresh cycle time is a time to execute the refresh command to refresh one of the plurality of memory cell rows of the memory cell array, and the row refresh cycle time is ended before another refresh command is issued.

2. The dynamic random access memory according to claim 1, wherein the first sub-period of the row refresh cycle time comprises a plurality of RAS active times, the refresh counter updates the current refresh word line address respectively during the RAS active times, and the refresh logic circuit refreshes the target row corresponding to the current refresh word line address during each of the RAS active times.

3. The dynamic random access memory according to claim 1, wherein the second sub-period of the row refresh cycle time comprises at least one RAS active time, the row hammer logic circuit updates the victim word line address during the at least one RAS active time, and the refresh logic circuit refreshes the victim row corresponding to the victim word line address during each of the at least one RAS active time.

4. The dynamic random access memory according to claim 3, wherein the RAS active time is a tRAS specified in a dynamic random access memory standard.

5. The dynamic random access memory according to claim 1, wherein the row refresh cycle time is a tRFC specified in a dynamic random access memory standard.

6. An operation method of a dynamic random access memory, the operation method comprising:
providing, by a refresh counter of the dynamic random access memory, a current refresh word line address for an automatic refresh operation, wherein the current refresh word line address corresponds to a target row in a plurality of memory cell rows of a memory cell array of the dynamic random access memory;
providing, by a row hammer logic circuit of the dynamic random access memory, a victim word line address for a row hammer protection, wherein the victim word line address corresponds to a victim row in the memory cell rows;
entering a row refresh cycle time based on a refresh command issued by a memory controller;
refreshing the target row by a refresh logic circuit of the dynamic random access memory during a first sub-period of the row refresh cycle time by using the current refresh word line address to perform the automatic refresh operation; and
refreshing the victim row by the refresh logic circuit during a second sub-period of the row refresh cycle time by using the victim word line address to perform the row hammer protection, wherein the row refresh cycle time is a time to execute the refresh command to refresh one of the plurality of memory cell rows of the memory cell array, and the row refresh cycle time is ended before another refresh command is issued.

7. The operation method according to claim 6, wherein the first sub-period of the row refresh cycle time comprises a plurality of RAS active times, and the operation method further comprises:
updating the current refresh word line address by the refresh counter respectively during the RAS active times; and
refreshing the target row corresponding to the current refresh word line address by the refresh logic circuit during each of the RAS active times.

8. The operation method according to claim 6, wherein the second sub-period of the row refresh cycle time comprises at least one RAS active time, and the operation method further comprises:
updating the victim word line address by the row hammer logic circuit during the at least one RAS active time; and
refreshing the victim row corresponding to the victim word line address by the refresh logic circuit during each of the at least one RAS active time.

9. The operation method according to claim 8, wherein the RAS active time is a tRAS specified in a dynamic random access memory standard.

10. The operation method according to claim 6, wherein the row refresh cycle time is a tRFC specified in a dynamic random access memory standard.
